(19) United States
(12) Patent Application Publication
(10) Pub. No.: US 2016/0155559 A1
(43) Pub. Date: Jun. 2, 2016

(54) ELECTRONIC PACKAGE

(71) Applicant: Siliconware Precision Industries Co., Ltd., Taichung (TW)

(72) Inventors: Chih-Hsien Chiu, Taichung (TW); Ming-Fan Tsai, Taichung (TW); Chia-Yang Chen, Taichung (TW); Chao-Ya Yang, Taichung (TW)

(21) Appl. No.: 14/695,076

(22) Filed: Apr. 24, 2015

(30) Foreign Application Priority Data
Nov. 28, 2014 (TW) 103141348

(51) Int. Cl. H01F 27/28; H01L 23/522; H01F 27/02; H01L 23/498; H01F 27/24; H01L 23/31; H01L 23/528

(52) U.S. Cl. CPC H01F 27/2804; H01L 23/3178; H01L 23/5227; H01L 23/528; H01L 23/5226; H01L 23/49811; H01F 27/24; H01F 27/022; H01F 2027/2809

(57) ABSTRACT

An electronic package is provided, including a substrate body, a ferromagnetic material embedded in the substrate body, and a conductor structure disposed around the conductor structure. Therefore, the conductor structure generates high magnetic flux and thus increases inductance.

### CROSS-REFERENCES TO RELATED APPLICATIONS

This application claims under 35 U.S.C. §119(a) the benefit of Taiwanese Application No. 103141348, filed Nov. 28, 2014, the entire contents of which are incorporated herein by reference.

### BACKGROUND OF THE INVENTION

1. Field of the Invention The present invention relates to electronic packages, and, more particularly, to an electronic package having a ferromagnetic material.

2. Description of Related Art

As the semiconductor packaging technology advances, electronic products have been developed towards high functionality and high performance In order to meet the demand of miniaturization for the packages, reducing the thickness of the substrate is now one of the primary endeavors in the industry. How compact and low-profile an electronic product could be is dependent on the requirements of the chip for high memory capacity, broadband, and low voltage, which is dependent on the wirings on the chip and integrations as well as the density of I/O connectors for providing the connections between the wiring signals of the electronic package and the power transfer media to enhance the memory capacity and operation frequency as well as reduced power supply for the chip.

In a typical semiconductor appliance, it is required to have passive components of radio frequency such as resistors, inductors, capacitors and oscillators being electrically connected to the semiconductor chip of the package, such that the semiconductor chip may have a certain currency property or to send certain signals.

Take a ball grid array (BGA) semiconductor device as an example. Most passive components, though disposed on the surface of a substrate, are traditionally disposed at the corners of the substrate or outside the chip mounting area of the substrate in order to prevent the passive components to interfere the electrical connection of the semiconductor chip and the bonding pads.

However, this act which limits the routability of the wirings on the substrate and the number of passive components to be disposed thereon due to the consideration of the positions of the bonding pads is a hindrance for high integration of the semiconductor device. Even more, as the requirement for increased number of passive components increases on the demands for higher performance requirements of the semiconductor package, the surface area of the substrate must increases causing the overall size of the package to increase, which is undesirable for low profile and compact size of the semiconductor package.

Based on the aforementioned problems, a solution is proposed to integrate the plurality of passive components to be disposed on the region of the substrate between the semiconductor chip and the bonding pads. As shown in a semiconductor package 1 of FIG. 1, a semiconductor chip 13 and a plurality of inductors 12 are disposed on a substrate 10 having a wiring layer 11, and the semiconductor chip 13 is electrically connected with bonding pads 110 of the wiring layer 11.

However, with the increasing number of I/O connectors on a unit area of the semiconductor deice, the number of bonding wires 130 must also increases. Since the height of a typical inductor 12 (0.8 mm) is greater than the height of the semiconductor chip 13 (0.55 mm), bonding wires 130 are easily in contact with the inductor 12, which causes a short circuit.

Another solution is proposed such that the loop height of the bonding wires 130 is raised to traverse above the inductors 12 to prevent the short circuit problem described above. However, this method is difficult which increases the complexity of the fabricating process, as well as the fabricating cost of the bonding wires 130. Moreover, as the bonding wire 130 has a certain weight, it could easily sag and make contact with the inductor 12 without a proper support, leading to short circuit.

Moreover, as the inductor 12 is a chip typed element, which is large in size, particularly in the inductor 12 required for power wiring, the parasitic effect may increase when the inductor 12 is getting far away from the semiconductor chip 13.

A further another solution is proposed to replace the inductor 12 with a coil type inductor 12′, as shown in FIG. 1′, to solve the aforementioned problems. However, the coil type inductor 12′ is only disposed on the substrate 10, such that the resulting simulated inductance of 17 nH (on an area of 2.0 mm×1.25 mm) is still too small to meet the requirement.

Thus, there is an urgent need for solving the foregoing problems.

### SUMMARY OF THE INVENTION

In view of the foregoing drawbacks of the prior art, the present invention provides a package structure, comprising: a substrate body having opposing first and second sides; a ferromagnetic material embedded in the substrate body and having a first surface facing the same direction as the first side of the substrate, a second surface opposing the first surface, and side surfaces abutting the first and second surfaces; and a conductor structure disposed around the ferromagnetic material.

In an embodiment, the substrate body comprises a core board having an opening, and the ferromagnetic material is disposed in the opening.

In an embodiment, the substrate body comprises an encapsulant, and the ferromagnetic material is embedded in the encapsulant.

In an embodiment, the ferromagnetic material is ferrite.

In an embodiment, the conductor structure is a loop coil, and the ferromagnetic material is located in the loop coil.

In an embodiment, the loop coil passes the first surface, one of the side surfaces, the second surface, and another one of the side surfaces of the ferromagnetic material sequentially. In another embodiment, the loop coil surrounds the side surfaces of the ferromagnetic material.

In an embodiment, the conductor structure has a metal layer formed on the first and second sides, and a plurality of conductive pillars coupled with the first and second sides and connected with the metal layer.

In an embodiment, the conductor structure makes contact with the ferromagnetic material.

In an embodiment, the conductor structure comprises a plurality of conductive traces formed on the ferromagnetic material.

In an embodiment, the ferromagnetic material is encapsulated by an encapsulant, and the encapsulant is embedded in the substrate body.

In an embodiment, the conductor structure is a wiring layer that is formed on the first surface and/or the second surface of the ferromagnetic material, rather than formed on the side surfaces of the ferromagnetic material.

In summary, in the electronic package according to the present invention, a conductor structure is used to surround the ferromagnetic material, such that the magnetic flux produced by the ferromagnetic material and the conductor structure as well as the inductance are increased.

Further, through the design of the ferromagnetic material, the inductance is increased for a single coil, compared with the conventional coil inductor without the ferromagnetic material, the present invention provides a solution to achieve the same inductance with smaller coil number, thereby facilitating miniaturization for the inductor.

### BRIEF DESCRIPTION OF THE DRAWINGS

FIGS. 1 and 1′ are schematic cross-sectional views showing a conventional semiconductor package;

FIG. 2A is a schematic cross-sectional view of an electronic package in accordance with a first embodiment of the present invention; wherein FIG. 2A′ is a partial 3D view of FIG. 2A;

FIG. 2B is a schematic cross-sectional view of an electronic package in accordance with a second embodiment of the present invention; wherein FIG. 2B′ is a partial 3D view of FIG. 2B;

FIG. 3 is a schematic cross-sectional view of an electronic package in accordance with a third embodiment of the present invention; wherein FIG. 3′ is a partial 3D view of FIG. 3, and FIG. 3″ is a partial top view of FIG. 3;

FIG. 4 is a schematic cross-sectional view of an electronic package in accordance with a fourth embodiment of the present invention; and

FIGS. 5A and 5B are schematic cross-sectional views of an electronic package in accordance with a fifth embodiment of the present invention; wherein FIG. 5A′ is a partial top view of FIG. 5A.

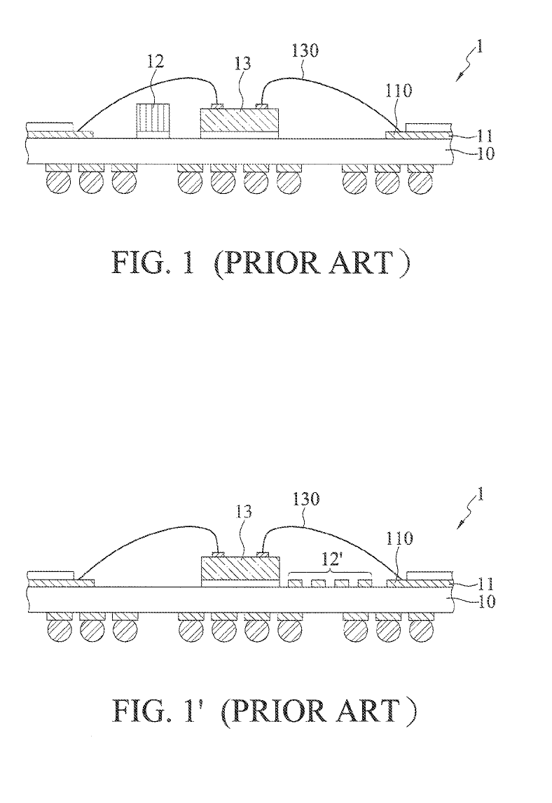

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “top”, “first”, “second”, “one” and etc., are merely for illustrative purpose and should not be construed to limit the scope of the present invention.

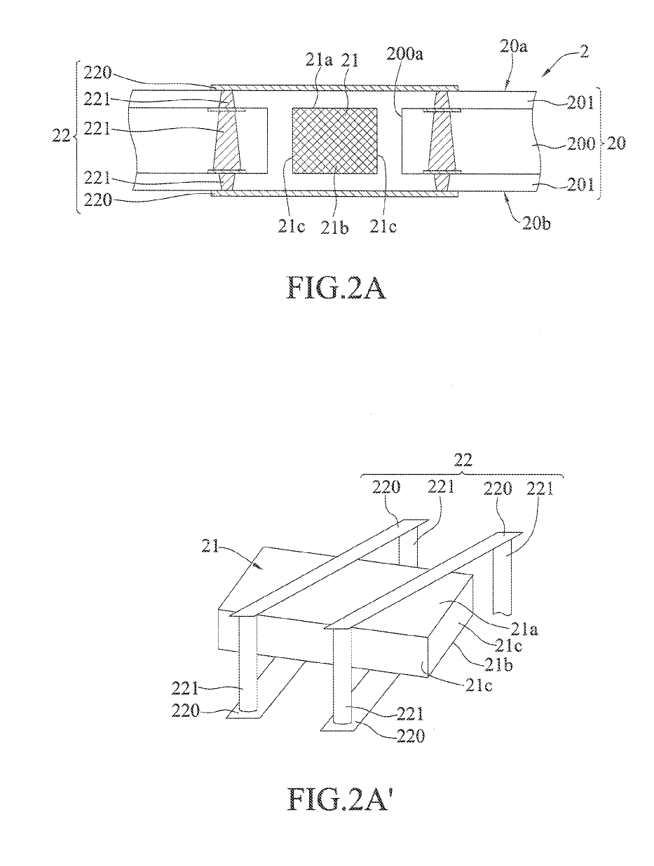

FIGS. 2A and 2A′ are schematic views of a electronic package 2 in accordance with a first embodiment of the present invention.

The electronic package 2 comprises: a substrate body 20, a ferromagnetic material 21 embedded in the substrate body 20, a conductor structure 22 disposed around the ferromagnetic material 21, an electronic component (not shown) disposed on the substrate body 20, and a wiring layer (not shown) coupled to the substrate body 20.

The substrate body 20 has opposing first and second sides 20a and 20b. In an embodiment, the substrate body 20 comprises a core board 200 having an opening 200a and a dielectric layer 201 covering the core board 200, and the ferromagnetic material 21 is positioned in the opening 200a, and encapsulated by the dielectric layer 201. The dielectric layer 201 serves as the surface of the first side 20a and the second side 20b. In an embodiment, the core board 200 is a ceramic substrate, a metal board, a copper foil substrate, or a wiring board.

The ferromagnetic material 21 is made of a high permeability material such as ferrite, and has a first surface 21a facing the same direction as the first side 20a, a second surface 21b opposing to the first surface 21a (facing the same direction as the second side 20b), and side surfaces 21c abutting the first and second surfaces 21a and 21b. The dielectric layer 201 flows in the opening 200a to cover the first surface 21a, the second surface 21b and the side surfaces 21c of the ferromagnetic material 21.

The conductor structure 22 and the ferromagnetic material 21 generate a magnetic flux, and form an inductor.

The electronic component is an active component, a passive component, or a combination thereof In an embodiment, the active component is a semiconductor chip, and the passive component is a resistor, a capacitor or an inductor. In an embodiment, the electronic component is an active component.

The wiring layer is formed on the core board 200 and the dielectric layer 201, and has a plurality of conductive vias (not shown) penetrating the core board 200 and the dielectric layer 201.

In an embodiment, the conductor structure 22 is a horizontal loop coil, and the ferromagnetic material 21 is positioned in the loop coil. In an embodiment, the loop coil passes the first surface 21a, one of the side surfaces 21c, the second surface 21b, and another one of the side surfaces 21c of the ferromagnetic material 21 sequentially.

In an embodiment, the conductor structure 22 has a metal layer 220 disposed on the metal layer 220 of the first side 20a and the second side 20b, and a plurality of conductive pillars 221 coupled with the first side 20a and the second side 20b and electrically connected to the metal layer. In an embodiment, the metal layer 220 is a wiring layer arranged in strips (as shown in FIG. 2A′), and disposed on the first surface 21a and second surface 21b of the ferromagnetic material 21 in position correspondingly, and the conductive pillars 221 are disposed corresponding to the side surfaces 21c of the ferromagnetic material 21.

During the fabrication process, the ferromagnetic material 21 is firstly positioned in the opening 200a, the dielectric layer 201 is then formed to encapsulate the ferromagnetic material 21, and the conductor structure 22 is formed.

In an embodiment, the metal layer 220 and the conductive pillars 221 are made of a copper material, and fabricated by a routing process.

FIGS. 2B and 2B′ are schematic views showing an electronic package 2′ in accordance with a second embodiment of the present invention. The second embodiment differs from the first embodiment in the loop coil and the substrate body. As shown in FIGS. 2B and 2B′, the conductor structure 22′ is a vertically arranged loop coil surrounding the side surfaces 21c of the ferromagnetic material 21.

In an embodiment, the metal layer 220′ is a winding trace layer, and disposed corresponding to the side surfaces 21c of the ferromagnetic material 21 in position, and the conductive pillars 221 are stacked on the metal layer 220′.

In an embodiment, the metal layer 220′ is a copper coil, and is fabricated by a routing process.

The substrate body 20′ has an encapsulant 200′ fabricated by a molding process to replace the core board 200, and the ferromagnetic material 21 is embedded in the encapsulant 200′, where a dielectric layer 201 is formed optionally. In an embodiment, if the encapsulant 200′ does not cover the first surface 21a and/or the second surface 2 lb of the ferromagnetic material 21, the dielectric layer 201 is formed by pressing against the first surface 21a and/or the second surface 21b of the ferromagnetic material 21. As shown in FIG. 2B, the dielectric layer 201 covers the first surface 21a and/or the second surface 21b of the ferromagnetic material 21. In another embodiment, if the encapsulant 200′ covers the first surface 21a, the second surface 21b and the side surfaces 21c of the ferromagnetic material 21, the dielectric layer 201 can be omitted.

In addition, the encapsulant 200′ described above can be used in the electronic package of the first embodiment.

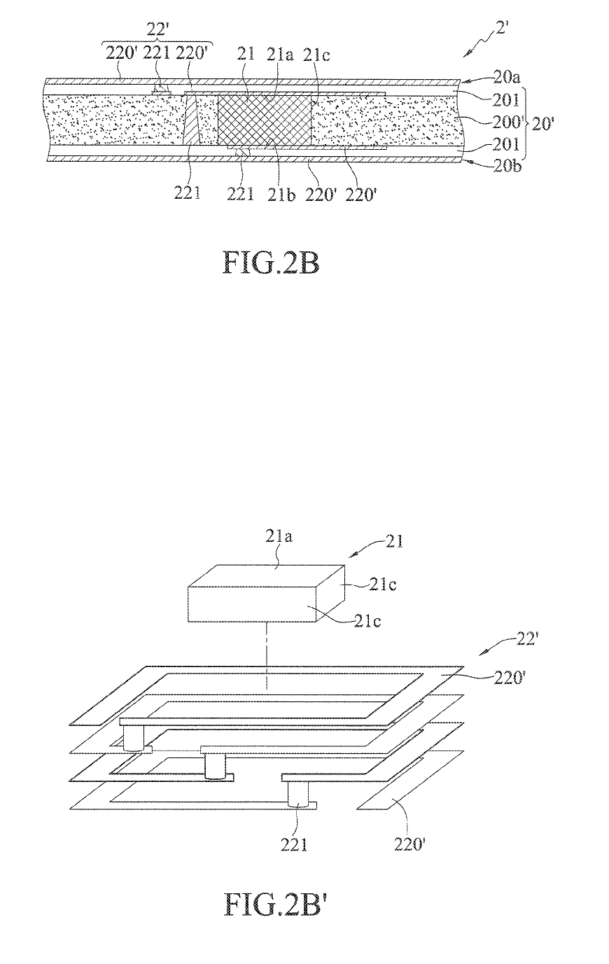

FIGS. 3, 3′ and 3″ are schematic views showing an electronic package 3 in accordance with a third embodiment of the present invention. The third embodiment differs from the first embodiment in the loop coil design.

As shown in FIGS. 3, 3′ and 3″, the conductor structure 32 makes contact with the ferromagnetic material 21.

In an embodiment, the conductor structure 32 comprises a plurality of traces 322 attached onto the ferromagnetic material 21, passing from the first surface 21a to the side surfaces 21c, and extending to the second surface 21b, and the conductive pillars 221 are in contact with the traces 322 on the first surface 21a and the second surface 21b, allowing the conductor structure 32 to form another loop coil in horizontal direction, and the ferromagnetic material 21 to be located in the loop coil.

The traces 322 can be fabricated by a sputtering, a coating, or a plating process. In an embodiment, the traces 322 can be applied in the electronic package of the second embodiment, and the metal layer 220′ or conductive pillars 221 are in contact with the traces 322.

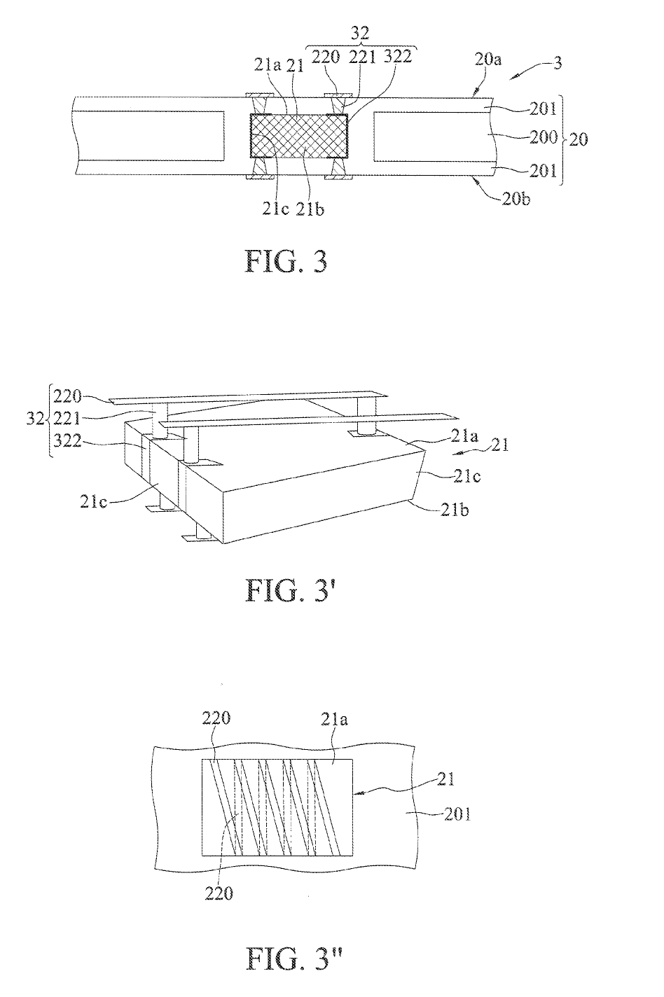

FIG. 4 is a schematic cross-sectional view of an electronic package 4 in accordance with a fourth embodiment of the present invention. The fourth embodiment differs from the first embodiment in the design of the ferromagnetic material.

As shown in FIG. 4, the ferromagnetic material 21 is encapsulated by an encapsulant 44, and the encapsulant 44 is embedded in the substrate body 20.

In an embodiment, the encapsulant 44 is formed to encapsulate the ferromagnetic material 21, the encapsulant 44 and the ferromagnetic material 21 are embedded in the opening 200a, and the dielectric layer 201 is formed to encapsulate the encapsulant 44. In an embodiment, the encapsulant 4 covers the first surface 21a, the second surface 21b and the side surfaces 21c of the ferromagnetic material 21.

In an embodiment, the metal layer 220 is a redistribution layer (RDL), and is formed on the core board 200 or on the dielectric layer 201 along with the wiring layer.

The example of the ferromagnetic material 21 encapsulated by the encapsulant 44 can be also applied in the electronic package of the second and third embodiment.

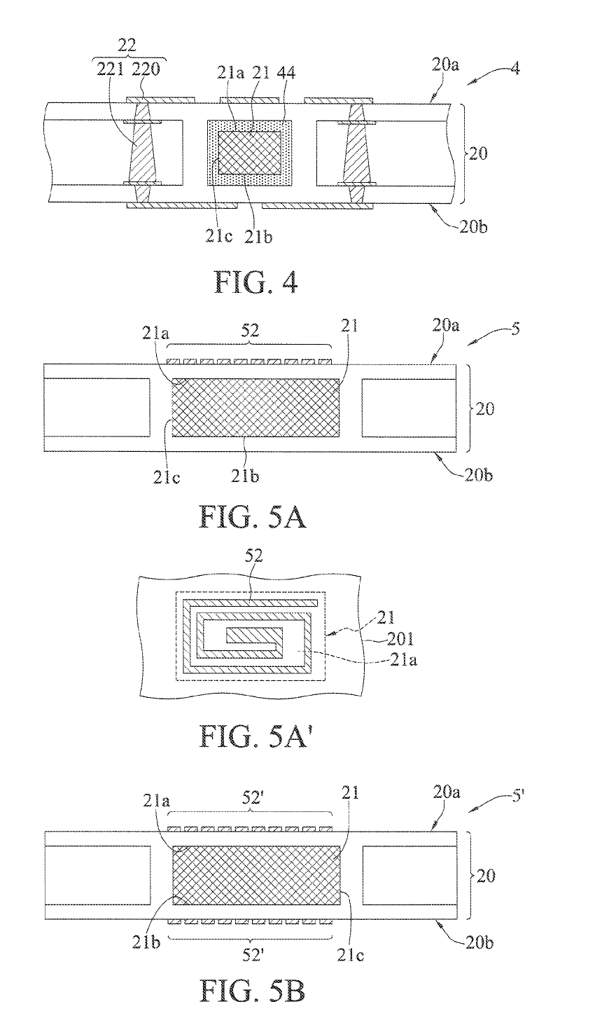

FIGS. 5A, 5A′ and 5B are schematic views showing electronic packages 5, 5′ in accordance with a fifth embodiment. The fifth embodiment differs from the first embodiment in the conductor structure.

As shown in FIGS. 5A and 5A′, the conductor structure 52 is a winding trace layer without conductive pillars. The conductor structure 52 is formed over the first surface 21a and/or over the second surface 21b, rather than formed over the side surfaces 21c of the ferromagnetic material 21.

In an embodiment, the conductor structure 52 is disposed corresponding in position on the first side 20a of the substrate body 20 on the first surface 21a of the ferromagnetic material 21. As shown in FIG. 5A′, the conductor structure 52 occupies an area above the first surface 21a.

Alternatively, as shown in FIG. 5B the conductor structure 52′ is disposed corresponding in position on the first side 20a of the substrate body 20 on the first surface 21a of the ferromagnetic material 21, and corresponding in position to the second side 20b of the substrate body 20 on the second surface 21b of the ferromagnetic material 21.

In addition, it is also applicable to apply the structures of the encapsulant 200′, traces 322 and conductive pillars 221, encapsulant 44 in the electronic package of the fifth embodiment.

The electronic package 2, 2′, 3, 4, 5, 5′ according to the present invention is characterized by having the conductor structures 22, 22′, 32, 52, 52′ surrounding the ferromagnetic material 21, such that the magnetic field is concentrated in the ferromagnetic path having low magnetic resistance, enabling the ferromagnetic material 21 to increase the magnetic flux, as well as the inductance, as a result the inductance can be raised to 75 nH according to the present invention, which is much higher than the prior art which has only 17 nH inductance.

Further, the design of the ferromagnetic material 21 allows an increase in the inductance for a single coil, thus fewer coil number are required to achieve the same level of inductance as compared to the conventional coil type inductance without using a magnetic. For instance, a conventional coil type of inductance requires 3 coils to reach the inductance level of 17 nH, but the loop coil of the present invention only requires one to reach 17 nH.

In addition, the inductor is constituted by the conductor structure 22, 22′, 32, 52, 52′ and the ferromagnetic material 21 according to the present invention, and has a size that is easily miniaturized according to a practical need. For instance, as the coil number of the loop coil according to the present invention is less than that of the conventional coil type inductance, the size of the inductance is reduced. Moreover, it is feasible to omit the wiring (i.e., a pure magnetic material) in the ferromagnetic material 21, hence the size can be reduced according to a practical needs, thereby meeting the requirement for miniaturization.

Accordingly, as compared to the conventional technology, the electronic packages 2, 2′, 3, 4, 5 and 5′ according to the present invention produce a larger inductance with a smaller routing area.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An electronic package, comprising:
a substrate body having opposing first and second sides;
a ferromagnetic material embedded in the substrate body, and having a first surface facing the same direction as the first side, a second surface opposing the first surface, and side surfaces abutting the first and second surface; and
a conductor structure disposed around the ferromagnetic material.

2. The electronic package of claim 1, wherein the substrate body comprises a core board having an opening, and the ferromagnetic material is positioned in the opening.

3. The electronic package of claim 1, wherein the substrate body comprises an encapsulant, and the ferromagnetic material is embedded in the encapsulant.

4. The electronic package of claim 1, wherein the ferromagnetic material is ferrite.

5. The electronic package of claim 1, wherein the conductor structure is a loop coil, and the ferromagnetic material is positioned in the loop coil.

6. The electronic package of claim 5, wherein the loop coil passes the first surface, one of the side surfaces, the second surface, and another one of the side surfaces of the ferromagnetic material sequentially.

7. The electronic package of claim 5, wherein the loop coil surrounds the side surfaces of the ferromagnetic material.

8. The electronic package of claim 1, wherein the conductor structure has a metal layer formed on the first side and the second side, and a plurality of conductive pillars coupled with the first side and the second side and connected with the metal layer.

9. The electronic package of claim 1, wherein the conductor structure is in contact with the ferromagnetic material.

10. The electronic package of claim 9, wherein the conductor structure comprises a plurality of traces formed on the ferromagnetic material.

11. The electronic package of claim 1, further comprising an encapsulant embedded in the substrate body and encapsulating the ferromagnetic material.

12. The electronic package of claim 1, wherein the conductor structure is a trace layer formed over the first surface and/or the second surface of the ferromagnetic material.
